(19) United States
(12) Patent Application Publication
(10) Pub. No.: US 2020/0032072 A1
(43) Pub. Date: Jan. 30, 2020

(54) COATING

(71) Applicant: P2i Ltd, Abingdon (GB)

(72) Inventors: Stephen Richard COULSON, (US); Delwyn EVANS, Abingdon Oxfordshire (GB); Angeliki SIOKOU, Abingdon Oxfordshire (GB); Clive TELFORD, Abingdon Oxfordshire (GB)

(21) Appl. No.: 15/735,121

(22) PCT Filed: Jun. 8, 2016
(86) PCT No.: PCT/GB2016/051687

§ 371 Date: Dec. 8, 2017

(30) Foreign Application Priority Data
Jun. 9, 2015 (EP) 15386019.2

(51) Int. Cl. C09D 5/00; C09D 165/00; C08G 61/04; H01R 13/40; H05K 3/28; C23C 16/505

(52) U.S. Cl. CPC C09D 5/00; C09D 165/00; C08G 61/04; H05K 2203/095; H05K 3/282; H05K 3/285; C23C 16/505; H01R 13/40

(57) ABSTRACT

An electronic or electrical device or component thereof comprising a protective polymeric coating on a surface of the electronic or electrical device or component thereof, wherein the polymeric coating is obtainable by exposing the electronic or electrical device or component thereof to a plasma comprising one or more saturated monomer compounds for a sufficient period of time to allow the protective polymeric coating to form on a surface thereof; wherein the one or more saturated monomer compounds each have a melting point at standard pressure of less than 45′C and a boiling point at standard pressure of less than 500° C.

### FIELD OF THE INVENTION

This invention relates to protective coatings. In particular, though not exclusively, the invention relates to substrates with protective coatings formed thereon, as well as methods of forming protective coatings on substrates.

### BACKGROUND TO THE INVENTION

It is well known that electronic and electrical devices are very sensitive to damage caused by contamination by liquids such as environmental liquids, in particular water. Contact with liquids, either in the course of normal use or as a result of accidental exposure, can lead to short circuiting between electronic components, and irreparable damage to circuit boards, electronic chips etc.

The problem is particularly acute in relation to small portable electronic equipment such as mobile phones, smartphones, pagers, radios, hearing aids, laptops, notebooks, tablet computers, phablets and personal digital assistants (PDAs), which can be exposed to significant liquid contamination when used outside or inside in close proximity of liquids. Such devices are also prone to accidental exposure to liquids, for example if dropped in liquid or splashed.

Other types of electronic or electrical devices may be prone to damage predominantly because of their location, for example outdoor lighting systems, radio antenna and other forms of communication equipment.

It is known in the art that applying a protective coating to electronic substrates presents particular difficulties. An electronic substrate may, in principle, be any electronic or electrical device or component that comprises at least one exposed electrical or electronic contact point. Such substrates are particularly vulnerable, e.g. on account of electrochemical migration, and require highly effective barrier and repellent protection against liquids, frequently over complex surfaces, e.g. circuit board topographies.

It is known to apply conformal coatings to electronic or electrical devices to protect moisture, dust, chemicals and temperature extremes by wet chemistry techniques, such as brushing, spraying and dipping. Conformal coatings take the 3D shape of the substrate on which they are formed and cover the entire surface of the substrate. For example, it is known to apply relatively thick protective coatings to electronic substrates based on parylene technology. A conformal coating formed in this way typically has a thickness of 30-130 μm for an acrylic resin, epoxy resin or urethane resin and 50-210 μm for a silicone resin.

The use of wet chemistry techniques to form these coatings has the disadvantage of the required use of solvents and associated environmental impact. In addition, wet chemistry techniques only allow exposed areas of the device or component to be coated, thus ‘hidden’ areas, for example recesses behind components can be left unprotected. Examples of such hidden areas on a mobile phone include the area under the RF shields, the screen FOG (flex on glass) connector, the inner parts of ZIF (zero insertion force) connectors.

In addition, electrical or electronic contact points of such substrates may lose their functionality if coated with an overly thick protective layer, on account of increased electrical resistance.

As conformal coatings formed by wet chemistry techniques are relatively thick, contact points are typically masked to prevent deposition of coating thereon. However, this leads to complex processing that is impractical on an industrial scale. In addition, the relatively thick coating can cause clogging in areas such as rotating shafts. An alternative method of protecting electronic and electrical devices is P2i's Splash-Proof™ technology, where an ultrathin repellent protective coating is applied to both the outside and the inside of an assembled electronic or electrical device. This restricts liquid ingress whilst additionally preventing any ingressed liquid spreading within the device. Thus, the vast majority of any liquid challenge is prevented from getting into the device in the first instance, whilst there is some additional protection within the device that does not interfere with the functionality of contact points. However, as this technology is directed to a liquid repellent coating rather than a physical barrier, it generally only provides protection against splashing and not against immersion of the device into liquid.

WO2007/083122 discloses electronic and electrical devices having a liquid repellent polymeric coating formed thereon by exposure to pulsed plasma comprising a particular monomer compound, for a sufficient period of time to allow a polymeric layer to form on the surface of the electrical or electronic devices. In general, an item to be treated is placed within a plasma chamber together with material to be deposited in the gaseous state, a glow discharge is ignited within the chamber and a suitable voltage is applied, which may be pulsed. This patent application is directed to a repellent coating rather than a physical barrier.

There remains a need in the art for highly effective protective coatings without the disadvantages of coatings applied by prior art methods. Such coatings could further enhance the resistance of substrates to liquids and/or enable more efficient manufacture of protected substrates, particularly in the electronics industry. It is an object of the invention to provide a solution to this problem and/or at least one other problem associated with the prior art.

### STATEMENTS OF THE INVENTION

According to a an aspect of the present invention there is provided an electronic or electrical device or component thereof comprising a protective polymeric coating on a surface of the electronic or electrical device or component thereof, wherein the polymeric coating is obtainable by exposing the electronic or electrical device or component thereof to a plasma comprising one or more saturated monomer compounds for a sufficient period of time to allow the protective polymeric coating to form on a surface thereof; wherein the one or more saturated monomer compounds each have a melting point at standard pressure of less than 45° C. and a boiling point at standard pressure of less than 500° C.

Preferably, each saturated monomer compound is a compound of formula (I):

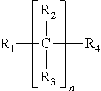

wherein each of R₁ to R₄ is independently selected from hydrogen, halogen and an optionally substituted C₁-C₆ cyclic, branched or straight chain alkyl group, and n is from 1 to 24.

The present invention provides a protective polymeric coating on a surface of the electronic or electrical device or component thereof by polymerising saturated monomer compounds. The benefits of using a saturated monomer as a starting material for the protective polymeric coating originate from the fact that they are more stable than unsaturated monomers (they do not polymerise like the unsaturated monomers) so they can be easily stored and transported. For the same reason, there is no need to add free radical inhibitors (stabilisers) and there is no need to consider their effects on storage and on the polymerisation process. In addition, since the saturated monomers are often less functionalised than unsaturated monomers, they can also be cheaper than unsaturated monomers.

High energy conditions are required to polymerise saturated monomers i.e monomers without a polymerizable structure such as a double or triple bond. This means that during the polymerisation process significant fragmentation of the hydrocarbon occurs, leading to crosslinking of the monomers.

Plasma polymerisation using saturated molecules described herein is not site specific due to the lack of the unsaturated bonds. This leads to more cross linked structures. The presence of a higher proportion of crosslinking in the polymer means that the polymer coating is denser and provides a physical barrier to mass and electron transport (i.e. restricts diffusion of water, oxygen and ions).

Preferably the saturated monomer compound has a melting point at standard pressure of less than 40° C., optionally less than 35° C., most preferably less than 30° C. Preferably the saturated monomer compound has a boiling point at standard pressure of less than 450° C., optionally less than 400° C., optionally less than 350° C., most preferably less 300° C.

The value of n may be from 1 to 22, 1 to 18, 1 to 16 or in a preferred embodiment n is from 8 to 14, optionally n is 12.

The halogen may be chorine or bromine but is preferably fluorine for compliance with RoHS regulations (Restriction of Hazardous Substances). The monomer may be a perfluoroalkane. The monomer may contain 1, 2, 3, 4, 5 or 6 fluoro groups.

In one embodiment, each of R₁ to R₄ is independently selected from hydrogen and an optionally substituted C₁-C₆ branched or straight chain alkyl group. The skilled person would be aware of possible substituents for the C₁-C₆ cyclic, branched or straight chain alkyl group. The skilled person would be aware that each C₁-C₆ cyclic, branched or straight chain alkyl group may be substituted with one or more saturated functional groups. If the alky group is substituted, a preferred substituent is halo, i.e. any of R₁ to R₄ may be haloalkyl, preferably fluoro alkyl. An alkyl group may be substituted with one or more fluoro groups. Any of R₁ to R₄ may be substituted with 1, 2, 3, 4, 5 or 6 fluoro groups. Any of R₁ to R₄ may be perfluoroalkyl groups. Any of the alkyl groups may also be substituted with one ore more hydroxyl groups.

Optionally each C₁-C₆ alkyl group may be independently selected from, methyl, ethyl, n-propyl, isopropyl, n-butyl, isobutyl, tert-butyl, sec-butyl, n-pentyl, neopentyl, n-hexyl, isohexyl, and 3-methylpentyl.

In a preferred embodiment R₁ and R₄ are both methyl.

In a preferred embodiment R₂ and R₃ are each independently selected from hydrogen and methyl. In a preferred embodiment each R₂ and R₃ is hydrogen.

In one preferred embodiment, R₁ and R₄ are both methyl and each R₂ and R₃ is hydrogen, i.e. the monomer is a straight chain alkane. In a particularly preferred embodiment, R₁ and R₄ are both methyl, each R₂ and R₃ is hydrogen, and n is from 8 to 14, most preferably 12.

The monomer may be a C₁-C₂₁ straight chain alkane, a C₁-C₈ straight chain alkane, a C₉-C₁₈ straight chain alkane, or a C₁₃ to C₁₆ straight chain alkane. The monomer may be a C₄-C₂₄ branched chain alkane, a C₄-C₈ branched chain alkane, a C₉-C₂₂ branched chain alkane, or a C₁₃ to C₁₆ branched chain alkane. It will be understood that the maximum number of carbon atoms for a branched chain alkane monomer will be higher than the maximum number of carbon atoms for a straight chain monomer to meet the requirement that the melting point of the monomer at standard pressure is less than 45° C. and the boiling point at standard pressure is less than 500° C.

Preferably, the monomer is selected from methane, ethane, propane, n-butane, iso-butane, n-pentane, isopentane, neo-pentane, n-hexane, 2-methyl pentane, 3-methyl pentane, 2,2-dimethyl butane, 2,3-dimethyl butane, n-heptane, 2-methylhexane, 3-methylhexane, 2,2-dimethylpentane, 2,3-dimethylpentane, 2,4-dimethylpentane, 3,3-dimethylpentane, 3-ethylpentane, 2,2,3-trimethylbutane, n-octane, 2-methylheptane, 3-methylheptane, 4-methylheptane, 2,2-dimethylhexane, 2,3-dimethylhexane, 2,4-dimethylhexane, 2,5-dimethylhexane, 3,3 dimethylhexane, 3,4-dimethylhexane, 3-ethylhexane, 2,2,3-trimethylpentane, 2,2,4-trimethylpentane, 2,3,3-trimethylpentane, 2,3,4-trimethylpentane, 3-ethyl-2-methylpentane, 3-ethyl-3-methylpentane, 2,2,3,3-tetramethylbutane, n-nonane and isomers thereof, n-decane and isomers thereof, n-undecane and isomers thereof, n-dodecane and isomers thereof, n-tridecane and isomers thereof, n-tetradecane and isomers thereof, n-pentadecane and isomers thereof, and n-hexadecane and isomers thereof. A particularly preferred monomer compound is n-tetradecane. Also suitable is 2,2,4,4,6,8,8-heptamethylnonane.

Table 1 provides a list of suitable straight chain alkane monomers and their corresponding melting and boiling points at standard (atmospheric) pressure.

TABLE 1

| n | n-Alkane | mp/° C. | bp/° C. |
|---|---|---|---|
| 1 | methane | −183 | −161 |
| 2 | ethane | −172 | −88 |
| 3 | propane | −188 | −42.1 |
| 4 | butane | −138 | −0.5 |
| 5 | pentane | −130 | 35-36 |
| 6 | hexane | −95 | 69 |
| 7 | heptane | −91 | 98 |
| 8 | octane | −57 | 125-127 |
| 9 | nonane | −53 | 151 |
| 10 | decane | −30 | 174 |
| 11 | undecane | −26 | 196 |
| 12 | dodecane | −9.6 | 215-217 |
| 13 | tridecane | −6-−4 | 110-112 |
| 14 | tetradecane | 5.5 | 252-254 |
| 15 | pentadecane | 8-10 | 270 |
| 16 | hexadecane | 18 | 287 |
| 17 | heptadecane | 20-22 | 302 |
| 18 | octadecane | 26-29 | 317 |
| 19 | nonadecane | 30-34 | 330 |
| 21 | heneicosane | 39-42 | 356 |

Chemical structures for some preferred branched chain alkane monomers are provided below:

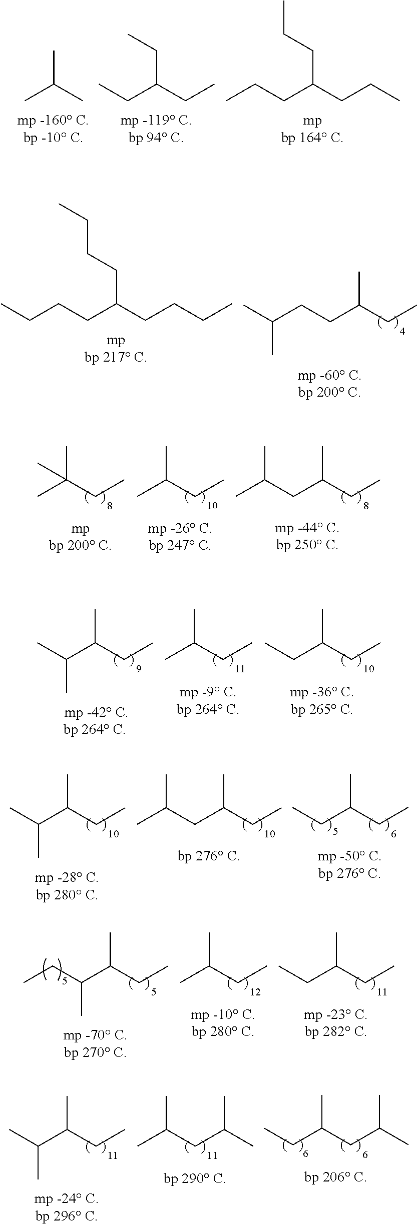

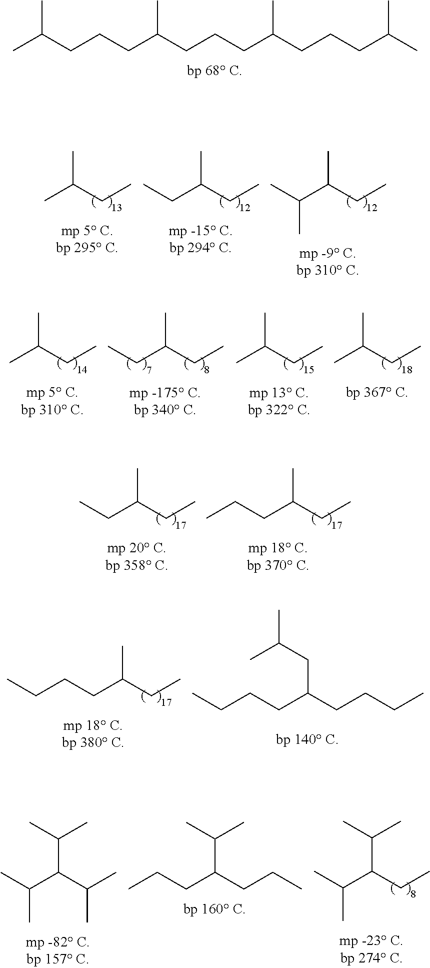

The plasma may comprise a single monomer compound. In this case, the coating is formed by polymerisation of the single monomer compound.

Alternatively, the plasma may comprise two different monomer compounds. In this case, the coating is formed by polymerisation of the two different monomer compounds to form a co-polymer. For example, the plasma may comprise a monomer compound and a co-monomer compound, wherein the monomer and co-monomer compounds have different chemical structures in accordance with formula (I). More than two different monomer compounds may also be contemplated.

The use of two or more different monomer compounds allows the coating properties to be tailored (for example hardness, surface finish and etching and polymer growth at the substrate/coating interface).

For example for coatings in areas prone to abrasion, the co-monomer may be selected to create a stronger interface with the substrate surface and/or a cap layer on top to protect the coating.

In a preferred embodiment the protective polymeric coating is a physical barrier. The term physical barrier is used to mean that the coating protects the electronic or electrical device or component thereof by providing a physical barrier to mass and electron transport, restricting the diffusion of water, oxygen and ions with time/voltage.

The coating may form a surface defined by a static water contact angle (WCA) of at least 70°. Coatings with a WCA of at least 90° may be described as liquid repellent (typically water repellent). In this case, the coating achieves liquid repellence in addition to providing a physical barrier. For fluorinated polymers, the coating may have a static water contact angle of at least 100°. The contact angle of a liquid on a solid substrate gives an indication of the surface energy which in turn illustrates the substrate's liquid repellence. Contact angles may be measured on a VCA Optima contact angle analyser, using 3 μl droplets of deionised water at room temperature.

In a particularly preferred embodiment the protective polymeric coating is a conformal polymeric coating over a surface of the device or component thereof.

When the coating is conformal, this means that it takes the 3D shape of the electronic or electrical device or component thereof and covers substantially an entire surface of the device. This has the advantage of ensuring that the coating has sufficient thickness to give optimal functionality over an entire surface of the device or component. The meaning of the term “covers substantially an entire surface” will depend to some extent on the type of surface to be covered. For example, for some components, it may be necessary for there to be complete coverage of the surface in order for the component to function after submersion in water. However, for other components or housings, small gaps in coverage may be tolerated.

The applicants have discovered that a conformal coating forming a physical barrier can be formed at much lower thicknesses than achieved in the prior art. This new thinner coating offers the protection of a physical barrier whilst using less monomer and having a shorter processing time, thus having both environmental and economic advantages.

The coating of the present invention is sufficiently thin to avoid clogging in critical areas such as rotating shafts.

The coating of the present invention is thin enough to enable electrical connection to electrical contact points without prior removal of the coating, therefore removing the need for electrical contact points to be masked during the coating process. This is particularly advantageous for components such as ZIF (Zero Insertion Force) connectors, headphone jacks and SIM card slots.

Different connectors apply different forces to the contact point (and thus coating) and can have differing surface profiles in contact with the contact point (for example flat, round or pointed).

Examples of suitable connectors include ZIF connectors, RF connectors, wiping contacts, contacts with high residual contact force (equilibrium force after insertion), spring connectors, headphone connectors and SIM card slots. For the purposes of the present invention, whether an electrical connection can be made through a coating is determined using a ZIF or RF connector.

The protective polymeric coating may have a thickness of from 50 to 10,000 nm, optionally 50 to 8000 nm, 100 to 5000 nm, preferably 250 nm-5000 nm, most preferably 250 nm-2000 nm. Coatings below 2,000 nm show good results for connections to headphones through the coating. Coatings below 1,000 nm show particularly good results for connections to spring connectors and SIM card slots through the coatings.

The protective polymeric coating may form a conformal physical barrier over substantially an external and/or internal surface of the device. For example, the protective polymeric coating may form a conformal physical barrier over substantially an entire external surface of the electronic or electrical device or component thereof.

In one embodiment, the electronic or electrical device or component thereof comprises a housing and the protective coating forms a conformal physical barrier over substantially an entire external and/or internal surface of the housing and/or on surfaces of components within the housing.

In one embodiment, the electronic or electrical device or component thereof comprises a housing and the protective polymeric coating forms a conformal physical barrier over substantially an entire internal surface of the housing and/or surfaces of components within the housing. In this embodiment adequate protection is provided by the coating on the internal surfaces; the external surface of the housing may not be provided with a coating, which may be advantageous for cosmetic regions as well as reducing processing steps.

The use of plasma polymerisation provides a coating with good thickness and quality homogeneity and allows non exposed areas on the electronic or electrical device or component thereof to be coated, for example recesses behind components which would not be accessible using wet chemistry techniques. In addition, the use of plasma polymerisation has the advantage of being a clean technique which does not require the use of solvents.

The coating may comprise one or more protective polymeric coating layers.

Preferably the protective polymeric coating is electrically insulating.

In one embodiment the electronic or electrical device or component thereof can withstand immersion in up to 1 m of water for over 30 minutes without failure or corrosion whilst power is applied to the electronic or electrical device or component.

Optionally, when the protective polymeric coating is applied on a test printed circuit board (PCB) it has a resistance of 8 MOhms or higher when submerged in water and a voltage of at least 16V/mm (for example 8V across a 0.5 mm gap between electrodes) is applied for a minimum of 13 minutes.

In one embodiment the coating is electrically insulating and the coating is sufficiently compliant that electrical connectors can be joined to the electronic or electrical device or component thereof and an electrical connection made between the electrical connectors and electronic or electrical device or component thereof without the requirement to first remove the coating.

Optionally the coating is electrically insulating and a force of less than 100 g applied to the coating using a round probe with 1 mm diameter allows an electrical connection to be made with the electronic or electrical device or component thereof in the local area where the force has been applied.

Optionally the coating is electrically insulating and has a thickness of 150 nm to 1000 nm and a force of less than 65 g applied to the coating using a round probe with 1 mm diameter allows an electrical connection to be made in the local area of the coating where the force has been applied.

Optionally the electronic or electrical device or component thereof comprises at least one electrical contact and wherein the at least one contact is covered by the coating.

The electronic or electrical device or component thereof is preferably selected from mobile phones, smartphones, pagers, radios, sound and audio systems such as loudspeakers, microphones, ringers and/or buzzers, hearing aids, personal audio equipment such as personal CD, tape cassette or MP3 players, televisions, DVD players including portable DVD players, video recorders, digi and other set-top boxes, computers and related components such as laptop, notebook, tablet, phablet, palmtop computers, personal digital assistants (PDAs), keyboards, or instrumentation, games consoles, data storage devices, outdoor lighting systems, radio antennae and other communications equipment and printed circuit boards.

In preferred embodiments of the invention, the substrate may comprise or consist of an electronic component, e.g. a printed circuit board (PCB), a printed circuit board array (PCBA), a transistor, resistor, or semi-conductor chip. The electronic component may thus be an internal component of an electronic device, e.g. a mobile phone. The coatings of the invention are particularly valuable in preventing electrochemical migration in such components.

In a further aspect, the present invention provides a method for treating an electronic or electrical device or component as defined in any preceding claim, comprising:

exposing said electronic or electrical device or component thereof to a plasma comprising one or more saturated monomer compounds for a sufficient period of time to allow a protective polymeric coating to form on a surface thereof; wherein the one or more saturated monomer compounds each have a melting point at standard pressure of less than 45° C. and a boiling point at standard pressure of less than 500° C.

Preferably, each monomer is a compound of formula (I):

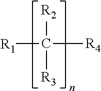

wherein each of R₁ to R₄ is independently selected from hydrogen, halogen and an optionally substituted C₁-C₆ branched or straight chain alkyl group, and n is from 1 to 24.

The monomer compound is as defined in detail above.

Optionally, the coating is built up in successive layers.

The plasma may comprise one monomer compound. In this case, the coating is formed by polymerisation of the single monomer compound.

Alternatively, the plasma may comprise two different monomer compounds. In this case, the coating is formed by polymerisation of the two different monomer compounds to form a co-polymer. For example, the plasma may comprise a monomer compound and a co-monomer compound, wherein the monomer and co-monomer compounds have different chemical structures in accordance with formula (I). More than two different monomer compounds may also be contemplated.

The coating may comprises one or more coating layers, wherein the total thickness of the one or more coating layers is within the range according to the first aspect. Alternatively the coating may comprise one or more coating layers, wherein the thickness of each coating layer is within the range according to the first aspect.

Ideally the monomer is gas or liquid at room temperature, so that it may be delivered into the plasma chamber.

The plasma is typically formed by applying a radio frequency signal to the one or more monomer compounds. Suitable plasmas for use in the methods of the invention include non-equilibrium plasmas such as those generated by radiofrequencies (Rf), microwaves or direct current (DC). They may operate at atmospheric or sub-atmospheric pressures as are known in the art. In particular however, they may be generated by radiofrequencies (Rf).

The plasma may be a pulsed wave (PW) plasma and/or a continuous wave (CW) plasma.

The coating is preferably substantially pin-hole free to enable it to provide a physical barrier. Preferably ΔZ/d<0.15, where ΔZ is the average height variation i.e. the surface profile measured on an AFM line scan and d is coating thickness. The value of ΔZ/d tells us to what extent defects on the surface of the coating extend into the coating, i.e. the percentage value of the depth of defect over total coating thickness. For example, ΔZ/d=0.15 means that the voids on the surface only extend down to 15% of the coating thickness. A coating with a ΔZ/d<0.15 is defined herein as being substantially pinhole free.

The coating may have a higher density than that of the corresponding monomer from which it is formed. For example, the increase in density may be at about 0.1 g/cm³. The increase in density is explained by a highly cross-linked coating. The high density of the coating improves the barrier properties of the coating.

The process parameters may comprise, for example, power, flow rate of monomer and monomer flow/power ratio.

Preferably the monomer flow rate at standard temperature and pressure is from 0.2 to 50, preferably 0.2 to 10 sccm, most preferably 0.25 to 1.0 sccm.

In a particularly preferred embodiment the power to monomer flow rate ratio is from 5 to 70 Watts/sccm, optionally 40 to 70 Watts/sccm, optionally 30 to 50 Watts/sccm.

The step of exposing said electronic or electrical device or component thereto to a plasma may take place in a reaction chamber

The step of exposing said electronic or electrical device or component thereof to a plasma may comprise a two step process, in which the first and second steps comprise different plasma conditions, for example a first continuous wave (CW) step and a second pulsed (PW) step.

The continuous wave (CW) deposition step has been found to act as a substrate priming step which optimise the coating's performance. The applicants have discovered that inclusion of a CW step optimises the interface between the substrate surface and growing coating, both causing some etching of the substrate surface and growth of the polymer coating. Inclusion of the CWdeposition step leads to homogenous growth of the coating and minimises the probability of the formation of defects in the coating.

The pulsed (PW) deposition step has been found to be important in achieving good ingress of the coating into difficult to access areas. The applicants have surprisingly discovered that the quality and thickness of coating on internal surfaces can be optimised by adjusting the flow and power parameters. Increased power provided good quality coatings with the desired functionality on internal surfaces. Increased flow provided good quality coatings with the desired functionality on external surfaces.

The flow rate of the monomer compound into the chamber may be lower (on a per volume basis of the chamber) than in the case of unsaturated monomers. Surprisingly, it has been found that high power/monomer flow ratios facilitate the formation of polymeric coatings having desirable barrier properties even at thicknesses that offer a low electrical resistance.

The exact flow rate of the monomer compound into the chamber may depend to some extent on the nature of the particular monomer compound being used, the nature of the substrate and the desired protective coating properties. In some embodiments of the invention the monomer compound is introduced into the chamber at a gas flow rate in the range of from 0.2 to 50 sccm, preferably 0.2 to 10 sccm and most preferably in the range of from 0.25 to 0.5 sccm, although this will depend on chamber volume. For a 2.51 chamber, the gas flow rate may be in the range of 0.3 to 0.5 sccm. The monomer gas flow is calculated from the liquid monomer flow considering that the monomer in the chamber acts like an ideal gas.

For pulsed plasmas, higher average powers can be achieved by using higher peak powers and varying the pulsing regime (i.e. on/off times).

From a further aspect, the invention resides in a method of forming a coating on an electronic or electrical device or component thereof, the method comprising: exposing said substrate in a chamber to a plasma comprising a monomer compound, preferably a pulsed plasma, for a sufficient period of time to allow a protective polymeric coating to form on the substrate, wherein during exposure of the substrate the pulsed plasma has a peak power (e.g. on-phase) of at least 8 W/litre.

In such a method the peak power density of the plasma is greatly in excess of that described in WO2007/083122. It has been found that this high power density of the plasma surprisingly facilitates the formation of polymeric coatings having desirable liquid repellent and/or barrier properties even at thicknesses that offer a low electrical resistance. This is due to the increased cross linking and/or fragmentation that occurs at higher powers.

The exact peak power density of the plasma will depend to some extent on the nature of the particular monomer compound being used, the nature of the substrate and the desired protective coating properties. In some embodiments of the invention, the plasma may have a peak on-phase power density in the range of from 3 to 30 W/litre, such as in the range of from 8 to 22 W/litre.

In one embodiment the plasma is a pulsed plasma in which pulses are applied in a sequence which yields a ratio of time on:time off in the range of from 0.5-0.001. For example, time on=35-45 μs and time off=from 0.1 ms to 10 ms, for example 0.5 ms. This pulsing regime gives a much higher average power than in prior art techniques, for example as disclosed in WO2007/083122, which contributes to the increased cross linking and/or fragmentation of the resulting polymer coating.

From a further aspect, the invention resides in a method of forming a coating on an electronic or electrical device or component thereof, the method comprising: exposing said substrate in a chamber to a plasma comprising a monomer compound, preferably a continuous plasma, for a sufficient period of time to allow a protective polymeric coating to form on the substrate, wherein during exposure of the substrate the continuous plasma has a power density of at least 8 W/litre.

From a further aspect, the invention resides in a method of forming a coating on an electronic or electrical device or component thereof, the method comprising: exposing said electronic or electrical device or component thereof in a chamber to a plasma comprising a monomer compound, preferably a pulsed plasma, for a sufficient period of time to allow a protective polymeric coating to form on the substrate, wherein during exposure of the substrate the pulsed plasma has a peak power to flow ratio of between 5 to 200 W/sccm, more preferably from 40-70 W/sccm, most preferably 60 Watts/sccm.

It has been found that this range of power to flow ratio surprisingly facilitates the formation of polymeric coatings having desirable liquid repellent and/or barrier properties even at very low thicknesses.

From a further aspect, the invention resides in a method of forming a coating on an electronic or electrical device or component thereof, the method comprising: exposing said electronic or electrical device or component thereof in a chamber to a plasma comprising a monomer compound, preferably a continuous plasma, for a sufficient period of time to allow a protective polymeric coating to form on the substrate, wherein during exposure of the substrate the continuous plasma has a power to flow ratio of between 5 to 200 W/sccm, more preferably from 40-70 W/sccm, most preferably 60 Watts/sccm.

The step of exposing said electronic or electrical device or component thereof to a plasma may comprise a pulsed (PW) deposition step. Alternatively, or in addition, the step of exposing said electronic or electrical device or component thereof to a plasma may comprise a continuous wave (CW) deposition step.

The aspects of the invention each provide methods facilitating the formation of highly effective protective coatings that can be applied to electronic substrates without interfering adversely with contact points. An advantage is that the resultant coating is sufficiently compliant such that electrical connectors can be joined after coating the device during or after manufacture and assembly. In one embodiment, the method includes the step of joining electrical connectors to the electronic or electrical device or component thereof after the coating has been applied. This has the advantage that electrical connectors can easily be joined to the electronic or electrical device or component thereof after coating the device or component during manufacture or assembly. In an alternative embodiment, the electrical connectors can be joined to the electronic or electrical device or component thereof before the coating has been applied.

Notably, the features of the aspects of the invention work in synergy and give rise to preferred embodiments of the invention when combined. All such combinations, with or without any of the preferred and optional features recited herein, are explicitly contemplated according to the invention.

In all aspects of the invention, the precise conditions under which the protective polymeric coating is formed in an effective manner will vary depending upon factors such as, without limitation, the nature of the monomer compound, the substrate, as well as the desired properties of the coating. These conditions can be determined using routine methods or, preferably, using the techniques and preferred features of the invention described herein, which work in particular synergy with the invention.

Suitable plasmas for use in the methods of the invention include non-equilibrium plasmas such as those generated by radiofrequencies (Rf), microwaves or direct current (DC). They may operate at atmospheric or sub-atmospheric pressures as are known in the art. In particular however, they may be generated by radiofrequencies (Rf).

Various forms of equipment may be used to generate gaseous plasmas. Generally these comprise containers or plasma chambers in which plasmas may be generated. Particular examples of such equipment are described for instance in WO2005/089961 and WO02/28548, the content of which is incorporated herein by reference, but many other conventional plasma generating apparatus are available.

In general, the substrate to be treated is placed within the plasma chamber together with the monomer compound, a glow discharge is ignited within the chamber, and a suitable voltage is applied. The voltage may be continuous wave or pulsed. Monomer may be introduced from the outset or following a period of preliminary continuous power plasma.

The monomer compound will suitably be in a gaseous state in the plasma. The plasma may simply comprise a vapour of the monomer compound if present. Such a vapour may be formed in-situ, with the compounds being introduced into the chamber in liquid form. The monomer may also be combined with a carrier gas, in particular, an inert gas such as helium or argon.

In preferred embodiments, the monomer may be delivered into the chamber by way of an aerosol device such as a nebuliser or the like, as described for example in WO2003/097245 and WO03/101621, the content of which is incorporated herein by reference. In such an arrangement a carrier gas may not be required, which advantageously assists in achieving high flow rates.

In some cases, a preliminary continuous power plasma may be struck for example for from 10 seconds to 10 minutes for instance for about 10 to 60 seconds, within the chamber. This may act as a surface pre-treatment step, ensuring that the monomer compound attaches itself readily to the surface, so that as polymerisation occurs, the coating “grows” on the surface. The pre-treatment step may be conducted before monomer is introduced into the chamber, for example in the presence of inert gas, or simply in a residual atmosphere. Monomer may then be introduced into the chamber to allow polymerisation to proceed, either switching the plasma to a pulsed plasma, continuing with a continuous plasma or using a sequence of both continuous and pulsed plasma.

In all cases, a glow discharge is suitably ignited by applying a high frequency voltage, for example at 13.56 MHz. This is suitably applied using electrodes, which may be internal or external to the chamber.

Gases, vapours or aerosols may be drawn or pumped into the plasma chamber or region. In particular, where a plasma chamber is used, gases or vapours may be drawn into the chamber as a result of a reduction in the pressure within the chamber, caused by use of an evacuating pump, or they may be pumped or injected into the chamber as is common in liquid handling.

Suitably the gas, vapour or gas mixture may be supplied at a rate of at least 0.04 sccm preferably from 0.2 to 50 sccm, preferably 0.2 to 10 sccm and most preferably in the range of from 0.25 to 0.5 sccm although this will depend on chamber volume. These amounts can be scaled up to larger systems on a chamber volume basis in accordance with the teaching herein.

Polymerisation is suitably effected using vapours of the monomer compound, which are maintained at pressures of from 0.1 to 200 mtorr, suitably at about 15-150 mtorr, preferably 30 to 60 mtorr, most preferably approximately 40 mtorr.

The applied fields may preferably provide a relatively high peak power density, e.g. as defined hereinabove in the method of the invention. The pulses may alternatively be applied in a sequence which yields a lower average power, for example in a sequence in which the ratio of the time on:time off is in the range of from 20:100 to 20:20000. Sequences with shorter time off periods may be preferred to maintain good power density. One example of a sequence is a sequence where power is on for 20 to 50 microseconds, for example 30 to 40 microseconds, such as about 36 microseconds, and off for from 5 to 30 milliseconds, for example 5 to 15 milliseconds, such as 6 milliseconds. This has been found to be of particular benefit when the monomer is a compound of formula (I).

Preferred average powers obtained in this way in a three litre chamber were in the range of from 0.05 to 25 W. In some embodiments, relatively low average powers are preferred, e.g. in the range of from 0.1 to 5 W, such as 0.15 to 0.5 W in a three litre chamber. Higher average powers, for example over 5 W have been found to have the advantage of aiding fragmentation of the monomer. These ranges may be scaled up or down on a volume basis for larger or smaller chambers and will depend on the selected peak power and pulse sequence.

The process temperatures, e.g. measured within the chamber, may be ambient, or preferably slightly above ambient, such as in the range of from 25 to 60° C., e.g. 35 to 55° C. In some embodiments, the process temperature is kept below 40° C. It is preferable to keep temperatures in the coating deposition process within a range which will not damage the electronic or electrical devices or components thereof. For example, the temperature is kept below 50° C. for mobile phones.

Suitably a plasma chamber used may be of sufficient volume to accommodate multiple substrates, in particular when these are small in size, for example up to 20,000 PCBs can be processed at the same time with ease with the correct size equipment. A particularly suitable apparatus and method for producing coated substrates in accordance with the invention is described in WO2005/089961, the content of which is hereby incorporated by reference.

The dimensions of the chamber will be selected so as to accommodate the entirety of the particular substrate being treated. For instance, generally cuboid chambers may be suitable for a wide range of applications, but if necessary, elongate or rectangular chambers may be constructed or indeed cylindrical, or of any other suitable shape. The volume of the chamber may, for example be at least 1 litre, preferably at least 8 litres. In some applications, relatively small chambers with a volume of up to 13 litres or up to 25 litres are preferred. For large scale production, the volume of the chamber may suitably be up to 400 litres or higher. The chamber may be a sealable container, to allow for batch processes, or it may comprise inlets and outlets for substrates, to allow it to be utilised in a continuous process. In particular in the latter case, the pressure conditions necessary for creating a plasma discharge within the chamber are maintained using high volume pumps, as is conventional for example in a device with a “whistling leak”. However it may also be possible to process certain substrates at atmospheric pressure, or close to, negating the need for “whistling leaks”.

Advantageously, electronic or electrical contact points of the substrate need not be masked during exposure, in particular for coating with a thickness below 5 μm, more preferably below 2 μm. Indeed, in one embodiment of the invention, such contacts are not masked during formation of the coating by any of the methods as described herein, leading to an advantageously simplified process.

More generally, from a further aspect, the invention resides in a substrate having a polymeric coating formed by any of the methods described herein. The invention also embraces coated substrates obtainable by any of the methods described herein.

One particular advantage of the invention is that electronic or electrical devices as a whole can be made resistant to liquids, even during full immersion, by coating only internal components such as PCBs, with an external coating no longer being necessary. Thus, from a further aspect, the invention resides in an electronic or electrical device, for example a mobile phone, comprising a housing and one or more internal electronic or electrical components with a coating formed thereon by any of the methods described herein. Advantageously, the housing need not comprise a coating. The device may advantageously pass standard IEC 60529 14.2.7 (IPX7).

More generally, any of the coated electronic substrates described herein may preferably continue to function even after full immersion into water for at least 2 minutes, preferably at least 5 minutes. The electronic substrate will preferably continue to function for at least 30 minutes or more preferably at least two days.

Aspects of the invention relating to methods of forming a coating on an electronic or electrical device or component thereof may be carried out using the monomers listed for the first aspect of the invention.

As used herein, the expression “in a gaseous state” refers to gases or vapours, either alone or in mixture, as well as optionally aerosols.

As used herein, the expression “protective polymeric coating” refers to polymeric layers which provide some protection against liquid damage, for example by forming a barrier and being liquid (such as oil- and/or water-) repellent. Sources of liquids from which the substrate is protected may include environmental liquids such as water, in particular rain, as well as liquids that may be accidentally spilled.

As used herein, the expression “during the exposure of the substrate” refers to a time period in which the substrate is within the chamber together with the plasma. In some embodiments of the invention, the expression may refer to the entire time period in which the substrate is within the chamber together with the plasma.

Throughout the description and claims of this specification, the words “comprise” and “contain” and variations of the words, for example “comprising” and “comprises”, mean “including but not limited to”, and do not exclude other moieties, additives, components, integers or steps. Moreover the singular encompasses the plural unless the context otherwise requires: in particular, where the indefinite article is used, the specification is to be understood as contemplating plurality as well as singularity, unless the context requires otherwise.

Preferred features of each aspect of the invention may be as described in connection with any of the other aspects. Other features of the invention will become apparent from the following examples.

Generally speaking the invention extends to any novel one, or any novel combination, of the features disclosed in this specification (including any accompanying claims and drawings). Thus features, integers, characteristics, compounds, chemical moieties or groups described in conjunction with a particular aspect, embodiment or example of the invention are to be understood to be applicable to any other aspect, embodiment or example described herein unless incompatible therewith. Moreover unless stated otherwise, any feature disclosed herein may be replaced by an alternative feature serving the same or a similar purpose.

Where upper and lower limits are quoted for a property, for example for the concentration of a monomer, then a range of values defined by a combination of any of the upper limits with any of the lower limits may also be implied.

The present invention will now be further described with reference to the following non-limiting examples and the accompanying illustrative drawings, of which:

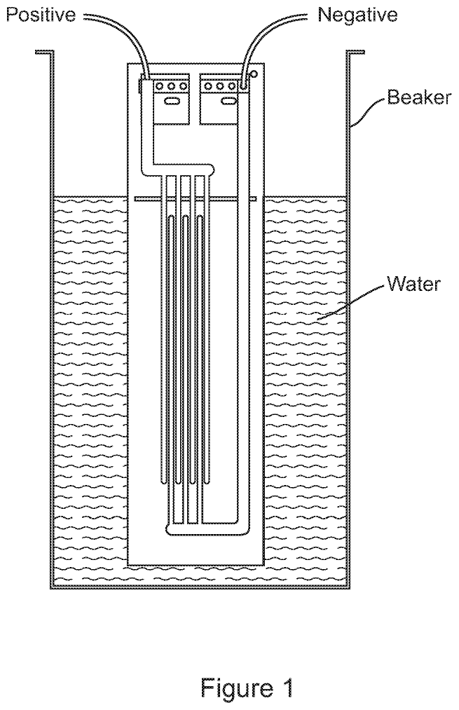

FIG. 1 illustrates the electrical test apparatus for determining the resistance of the coating

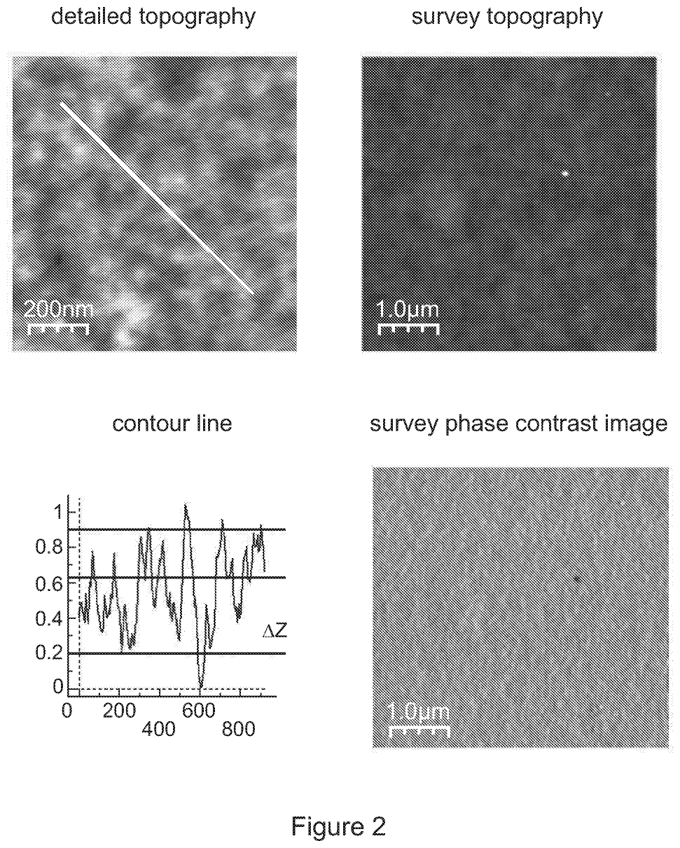

FIG. 2 shows a tapping mode image of a 1700 nm thick coating, prepared as described in example 1 over 1×1 μm² field of view (top left), a 5×5 μm² field of view (top right), a representative contour line indicating height variation (z-axis) of the coating (bottom left) and a phase image indicating full substrate coverage (bottom right); RMS roughness of the coating is 0.4 nm and Δz/d=0.0006.

### EXAMPLE 1

Process Set Up and Parameters

Plasma polymerization experiments were carried out in a cylindrical glass reactor vessel with a volume of 2.5 liters. The vessel was in two parts, coupled with a Viton O-ring to seal the two parts together under vacuum. One end of the reactor was connected to a liquid flow controller which was heated at 70° C. and this was used for delivering monomer at a controlled flow rate.

The other end of the reactor was connected to a metal pump line fitted with pressure gauges, pressure controlling valve, liquid nitrogen trap and a vacuum pump. A copper coil electrode was wrapped around the outside of the reactor (11 turns of 5 mm diameter piping) and this was connected to a RF power unit via an L-C matching network. For pulsed plasma deposition the RF power unit was controlled by a pulse generator.

The monomer used was n-tetradecane (CAS no. 16646-44-9), a saturated monomer in accordance with the present invention

The reactor was evacuated down to base pressure (typically <10 mTorr). The monomer was delivered into the chamber using the flow controller, at a monomer gas flow of 0.4 sccm. The chamber was heated to 45° C. The pressure inside the reactor was maintained at 30 mTorr. The plasma was produced using RF at 13.56 MHz and the process typically consisted of two main steps; the continuous wave (CW) plasma and the pulsed wave (PW). The CW plasma was for 2 minutes and the duration of the PW plasma varied in different experiments. The peak power setting was 30 W, and the pulse conditions were time on (Tₒₙ)=37 μs and time off (T_{off})=0.5 ms. At the end of the deposition the RF power was switched off, the flow controller stopped and the chamber pumped down to base pressure. The chamber was then vented to atmospheric pressure and the coated samples removed.

For each experiment, two test PCBs and two Si wafers were used. The Si wafers allow physical properties of the formed coating to be measured, for example AFM for surface morphology. The metal tracks of the test PCBs were gold coated copper. The Si wafers were placed on the top front side of the PCBs.

The process parameters for the experiments are shown in Table 2.

### EXAMPLE 2

Resistance at Fixed Voltage Over Time

This test method has been devised to evaluate the ability of different coatings to provide an electrical barrier on printed circuit boards and predict the ability of a smart phone to pass the IEC 60529 14.2.7 (IPX7) test. The method is designed to be used with tap water. This test involves measuring the current voltage (IV) characteristics of a standardised printed circuit board (PCB) in water. The PCB has been designed with a 0.5 mm spacing between electrodes to allow assessment of when electrochemical migration occurs across the tracks in water. The degree of electrochemical activity is quantified by measuring current flow; low current flow is indicative of a good quality coating. The method has proved to be extremely effective at discriminating between different coatings. The performance of the coatings can be quantified, e.g. as a resistance at 4V, 8V and 21 V. The measured resistance on the untreated test device is about 100 ohms when a voltage of 8V is applied.

The coated PCB to be tested is placed into a beaker of water and connected to the electrical test apparatus as shown FIG. 1. The board 10 is centred horizontally and vertically in the beaker 12 of water 14 to minimise effects of local ion concentration (vertical location of the board is very important; water level should be to the blue line). When the PCB is connected, the power source is set to the desired voltage and the current is immediately monitored. The voltage applied is 8V and the PCB is held at the set voltage for 13 minutes, with the current being monitored continuously during this period.

The coating formed by the process parameters shown in Table 2 is tested and the results are shown in Table 3. It has been found that when coatings have resistance values higher than 8 MOhms, the coated device will pass successfully an IPX7 test. The nature of the device being coated (for example the type of smart phone) will influence the test, for example due to the variations in materials, ingress points, power consumption etc).

Critical Force (Fc)

The electrical conductivity of a coating can change significantly when a compressive stress is applied to the coating. The change in the electrical conductivity will depend on the amplitude of strain experienced by the coating, amount of defects and type of polymer matrix of the coating. This behaviour is explained on the basis of formation or destruction of a conductive network, which further depends on the viscosity (stiffness) of the polymer matrix. To evaluate the ability of the coating to provide electrical contact under relatively low force, a contact force test is performed.

The contact force test is an electrical test procedure which involves measuring the critical force (Fc) or pressure (Pc) that has to be applied to the insulating coating via a flat probe, for electrical break down through the coating to occur. The test can be used either on PCBs of smart phones or on strip boards (Test PCBs) which are placed as witness samples during processes.

The test uses a flat probe 1 mm in diameter (or a spherical probe of 2 mm diameter), contacting the planar film's surface. The probe is mounted on a support stand and the arrangement is such that variations in the force applied by the probe to the surface of the sample are immediately recorded by a weighing scale (or load cell) on which the sample is placed. With this arrangement the resolution in applied pressure is about 15 KPa (force 5 g).

The normal procedure is to manually ramp the force applied by the probe on the planar surface of the sample while observing the resistance between the probe and the conductive substrate. The force is manually or automatically increased up to the point (Fc) where current break down through the film occurs.

This test allows the electrical insulation characteristics of the sample to be analyzed at a number of different points across the surface thus providing an idea of the uniformity of the surface layer.

The Fc value for the coated PCB coating formed in Example 1 is shown in Table 3.

Coating Thickness

The thickness of the coatings formed in Example 1 was measured using spectroscopic reflectometry apparatus (Filmetrics F20-UV) using optical constants verified by spectroscopic elipsometry.

Spectroscopic Reflectometry

Thickness of the coating is measured using a Filmetrics F20-UV spectroscopic reflectometry apparatus. This instrument (F20-UV) measures the coating's characteristics by reflecting light off the coating and analyzing the resulting reflectance spectrum over a range of wavelengths. Light reflected from different interfaces of the coating can be in- or out-of-phase so these reflections add or subtract, depending upon the wavelength of the incident light and the coating's thickness and index. The result is intensity oscillations in the reflectance spectrum that are characteristic of the coating.

To determine the coating's thickness, the Filmetrics software calculates a theoretical reflectance spectrum which matches as closely as possible to the measured spectrum. It begins with an initial guess for what the reflectance spectrum should look like, based on the nominal coating stack (layered structure). This includes information on the thickness (precision 0.2 nm) and the refractive index of the different layers and the substrate that make up the sample (refractive index values can be derived from spectroscopic ellipsometry). The theoretical reflectance spectrum is then adjusted by adjusting the coating's properties until a best fit to the measured spectrum is found. Measured coatings must be optically smooth and within the thickness range of from 1 nm to 40 μm.

Surface Morphology

The surface morphology of the coatings is measured using atomic force microscopy (AFM). Analyses are carried out with a Veeco Park Autoprobe AFM instrument, operated in the tapping imaging mode, using Ultrasharp NSC12, diving-board levers with spring constants in the range 4-14 N/m, and with resonant frequencies in the range 150-310 kHz. A high-aspect ratio probe, with a radius of curvature at the tip apex of <10 nm and opening angle <20° was used. Fields of view of 5×5 and 1×1 μm² were imaged, with the larger field of view being the more informative. Surface roughness, RMS (root mean square), was calculated by standard software, for each field of view. The images obtained were 256×256 pixels in all cases.

From the AFM morphological analysis of the coatings two parameters can be extracted; (a) the RMS roughness (r) of the coating and b) the ratio ΔZ/d whereas d is the thickness of the coating and ΔZ is explained below.

FIG. 2 shows a tapping mode image over 1×1 μm² field of view of a specimen example (thickness d=1700 nm) prepared according to Example 1 (left hand side) and a contour line plot showing the data used for calculation of RMS roughness (right hand side). The ΔZ value indicated on the plot has been taken over an area of the graph that represents the majority of the coating. Peaks that lie above the ΔZ range indicate large particles and troughs that fall below the ΔZ range show voids or pinholes in the coating. The width of the peaks also gives an indication of the particle size.

For the sample in Table 3, RMS roughness(r) was 0.4 nm and ΔZ=1±0.2 nm giving ΔZ/d=0.0006.

It has been shown that ΔZ/d<0.15, indicates a pinhole free coating. Morphological parameters are good indicators for pinhole free coatings. However, this property alone does not account for the high performance of the coating.

On examination the coatings were found to be conformal and the fact that all of the coatings either exceed the IPX7 test or are close to it are indicative that they form physical barriers. The use of plasma polymerisation to deposit the coating has the advantage that the coating can be made sufficiently thick to provide a physical barrier whilst being significantly thinner than prior art conformal coatings. This thickness range has the advantage that it is sufficiently thick to form a physical barrier yet thin enough to allow electrical connections to be made without first removing it.

The use of plasma polymerisation also has the advantage that good ingress of the monomer during the plasma polymerisation technique ensures that the coating covers all of the desired areas, for example the entire external surface. Where the electronic or electrical device comprises a housing, the entire internal surface of the housing can be coated (by exposing the open housing to the plasma) to protect the electronic components inside the housing once the device is assembled.

TABLE 2
process parameters for a coating formed from n-Tetradecane.

| | | |
|---|---|---|
| CW time | 2 | min |
| Ton | 37 | μs |
| Toff | 0.5 | ms |
| monomer pressure | 30 | mtorr |
| PW/CWpower | 30 | Watts |
| monomer flow rate (STP) | 0.40 | sccm |
| Chamber T | 45° | C. |
| PW time | 45 | min |
| power/volume | 12 | Watts/litre |
| power/flow | 75 | Watts/sccm |
| monomer volume/min | 0.005 | ml/min |

TABLE 3
coating properties for a coating formed from n-Tetradecane.

| | | |
|---|---|---|
| Thickness (d) Si | 968 | nm |
| Thickness (d) SB | 1135 | nm |
| R at 8 V 13 min | 4.78E+07 | Ω |
| R/d (13 min) | 4.21E+04 | Ω/nm |
| Critical force | 60 | g |
| RMS roughness (AFM) | 0.4 | nm |
| ΔZ (AFM) | 1 ± 0.2 | nm |

1. An electronic or electrical device or component thereof comprising a protective polymeric coating on a surface of the electronic or electrical device or component thereof, wherein the polymeric coating is obtainable by exposing the electronic or electrical device or component thereof to a plasma comprising one or more saturated monomer compounds for a sufficient period of time to allow the protective polymeric coating to form on a surface thereof; wherein the one or more saturated monomer compounds each have a melting point at standard pressure of less than 45° C. and a boiling point at standard pressure of less than 500° C.

2. An electronic or electrical device or component thereof according to claim 1 wherein each saturated monomer compound is a compound of formula (I): 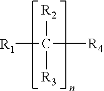
wherein each of R₁ to R₄ is independently selected from hydrogen, halogen and an optionally substituted C₁-C₆ cyclic, branched or straight chain alkyl group, and n is from 1 to 24.

3. An electronic or electrical device or component thereof according to claim 1 or claim 2, wherein the plasma comprises a single saturated monomer compound.

4. An electronic or electrical device or component thereof according to claim 1 or claim 2, wherein the saturated monomer compounds comprise a monomer compound and a co-monomer compound, wherein the monomer and co-monomer compounds have different chemical structures in accordance with formula (I).

5. An electronic or electrical device or component thereof according to any preceding claim, wherein n is from 1 to 16.

6. An electronic or electrical device or component thereof according to any preceding claim, wherein n is from 8 to 14.

7. An electronic or electrical device or component thereof according to any preceding claim, wherein the halogen is fluorine.

8. An electronic or electrical device or component thereof according to any of claims 1 to 6, wherein each of R₁ to R₄ is independently selected from hydrogen and an optionally substituted C₁-C₆ cyclic, branched or straight chain alkyl group.

9. An electronic or electrical device or component thereof according to any preceding claim, wherein each C₁-C₆ alkyl group is independently selected from, methyl, ethyl, n-propyl, isopropyl, n-butyl, isobutyl, tert-butyl, sec-butyl, n-pentyl, neopentyl, n-hexyl, isohexyl, and 3-methylpentyl.

10. An electronic or electrical device or component thereof according to claim 8, wherein R₁ and R₄ are both methyl.

11. An electronic or electrical device or component thereof according to any preceding claim, wherein R₂ and R₃ are each independently selected from hydrogen and methyl.

12. An electronic or electrical device or component thereof according to claim 11, wherein each R₂ and R₃ is hydrogen.

13. An electronic or electrical device or component thereof according to claim 12, wherein R₁ and R₄ are both methyl, each R₂ and R₃ is hydrogen, and n is from 1 to 18.

14. An electronic or electrical device or component thereof according to any preceding claim, wherein the monomer is selected from methane, ethane, propane, n-butane, iso-butane, n-pentane, isopentane, neo-pentane, n-hexane, 2-methyl pentane, 3-methyl pentane, 2,2-dimethyl butane, 2,3-dimethyl butane, n-heptane, 2-methylhexane, 3-methylhexane, 2,2-dimethylpentane, 2,3-dimethylpentane, 2,4-dimethylpentane, 3,3-dimethylpentane, 3-ethylpentane, 2,2,3-trimethylbutane, n-octane, 2-methylheptane, 3-methylheptane, 4-methylheptane, 2,2-dimethylhexane, 2,3-dimethylhexane, 2,4-dimethylhexane, 2,5-dimethylhexane, 3,3 dimethylhexane, 3,4-dimethylhexane, 3-ethylhexane, 2,2,3-trimethylpentane, 2,2,4-trimethylpentane, 2,3,3-trimethylpentane, 2,3,4-trimethylpentane, 3-ethyl-2-methylpentane, 3-ethyl-3-methylpentane, 2,2,3,3-tetramethylbutane, n-nonane and isomers thereof, n-decane and isomers thereof, n-undecane and isomers thereof, n-dodecane and isomers thereof, n-tridecane and isomers thereof, n-tetradecane and isomers thereof, n-pentadecane and isomers thereof, and n-hexadecane and isomers thereof.

15. An electronic or electrical device or component thereof according to any preceding claim, wherein the protective polymeric coating is a liquid repellent layer.

16. An electronic or electrical device or component thereof according to claim 15 wherein the protective polymeric coating is defined by a static water contact angle (WCA) of at least 90°.

17. An electronic or electrical device or component thereof according to any preceding claim, wherein the protective polymeric coating is a physical barrier to mass and/or electron transport.

18. An electronic or electrical device or component thereof according to any preceding claim, wherein the protective polymeric coating is a conformal polymeric coating over a surface of the device or component thereof.

19. An electronic or electrical device or component thereof according to claim 18, wherein the protective polymeric coating forms a conformal polymeric coating over substantially an entire external surface of the electronic or electrical device or component thereof.

20. An electronic or electrical device or component thereof according to claim 18 or claim 19 wherein the electronic or electrical device or component thereof comprises a housing and wherein the coating forms a conformal polymeric coating over substantially an entire external and/or internal surface of the housing.

21. An electronic or electrical device or component thereof according to any of claims 18 to 20 wherein the electronic or electrical device or component thereof comprises a housing and wherein the protective polymeric coating forms a conformal physical barrier over substantially an entire external surface of components within the housing.

22. An electronic or electrical device or component thereof according to any preceding claim wherein the coating comprises two or more protective polymeric coating layers.

23. An electronic or electrical device or component according to any preceding claim, wherein the protective polymeric coating has a thickness of from 50 nm-10,000 nm.

24. An electronic or electrical device or component thereof according to claim 23, wherein the coating has a thickness in the range of 100 nm to 5000 nm.

25. An electronic or electrical device or component thereof according to claim 24, wherein the coating has a thickness in the range of 250 nm to 2000 nm.

26. An electronic or electrical device or component thereof according to any preceding claim, wherein the coating is electrically insulating.

27. An electronic or electrical device or component thereof according to any preceding claim, wherein the electronic or electrical device or component thereof can withstand immersion in up to 1 m of water for over 30 minutes without failure or corrosion whilst power is applied to the electronic or electrical device or component.

28. An electronic or electrical device or component thereof according to any of the preceding claims, wherein the coating has a resistance of 8 MOhms or higher when submerged in water and a voltage of at least 16V/mm is applied for a minimum of 13 minutes.

29. An electronic or electrical device or component according to any of the preceding claims, wherein the coating is electrically insulating and wherein the coating is sufficiently compliant that electrical connectors can be joined to the electronic or electrical device or component thereof and an electrical connection made between the electrical connectors and electronic or electrical device or component thereof without the requirement to first remove the coating.

30. An electronic or electrical device or component according to any preceding claim, wherein the coating is electrically insulating and wherein a force of less than 100 g applied to the coating using a round probe with 1 mm diameter allows an electrical connection to be made with the electronic or electrical device or component thereof in the local area where the force has been applied.

31. An electronic or electrical device or component according to any of the preceding claims, wherein the coating is electrically insulating and has a thickness of 150 nm to 1000 nm and wherein a force of less than 65 g applied to the coating using a round probe with 1 mm diameter allows an electrical connection to be made in the local area of the coating where the force has been applied.

32. An electronic or electrical device or component thereof according to any preceding claim wherein the electronic or electrical device or component thereof comprises at least one electrical contact and wherein the at least one contact is covered by the coating.

33. An electronic or electrical device or component thereof according to any of the preceding claims, wherein the electronic or electrical device or component thereof is selected from mobile phones, smartphones, pagers, radios, sound and audio systems such as loudspeakers, microphones, ringers and/or buzzers, hearing aids, personal audio equipment such as personal CD, tape cassette or MP3 players, televisions, DVD players including portable DVD players, video recorders, digi and other set-top boxes, computers and related components such as laptop, notebook, tablet, phablet, palmtop computers, personal digital assistants (PDAs), keyboards, or instrumentation, games consoles, data storage devices, outdoor lighting systems, radio antennae and other communications equipment and printed circuit boards.

34. A method for treating an electronic or electrical device or component as defined in any preceding claim, comprising:
exposing said electronic or electrical device or component thereof to a plasma comprising one or more saturated monomer compounds for a sufficient period of time to allow a protective polymeric coating to form on a surface thereof; wherein the one or more saturated monomer compounds each have a melting point at standard pressure of less than 45° C. and a boiling point at standard pressure of less than 500° C.

35. A method according to claim 34, wherein each saturated monomer compound is a compound of formula (I): 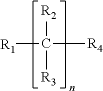
wherein each of R₁ to R₄ is independently selected from hydrogen, halogen and an optionally substituted C₁-C₆ cyclic, branched or straight chain alkyl group, and n is from 1 to 24.

35. A method according to claim 34 or claim 35, wherein the plasma comprises a single monomer compound.

36. A method according to claim 34 or claim 35, wherein the plasma comprises a monomer compound and a co-monomer compound, wherein the monomer and co-monomer compounds have different chemical structures in accordance with formula (I).

37. A method according to any of claims 34 to 36, wherein n is from 1 to 16, optionally n is from 8 to 14.

38. A method according to any of claims 34 to 36, wherein the halogen is fluorine.

39. A method according to any of claims 34 to 38, wherein each of R₁ to R₄ is independently selected from hydrogen and an optionally substituted C₁-C₆ cyclic, branched or straight chain alkyl group.

40. A method according to any of claims 34 to 39, wherein each C₁-C₆ alkyl group is independently selected from, methyl, ethyl, n-propyl, isopropyl, n-butyl, isobutyl, tert-butyl, sec-butyl, n-pentyl, neopentyl, n-hexyl, isohexyl, and 3-methylpentyl.

41. A method according to claim 40, wherein R₁ and R₄ are both methyl.

42. A method according to any of claims 34 to 41, wherein R₂ and R₃ are each independently selected from hydrogen and methyl.

43. A method according to claim 42, wherein each R₂ and R₃ is hydrogen.

44. A method according to any of claims 34 to 43, wherein each monomer is independently selected from methane, ethane, propane, n-butane, iso-butane, n-pentane, isopentane, neo-pentane, n-hexane, 2-methyl pentane, 3-methyl pentane, 2,2-dimethyl butane, 2,3-dimethyl butane, n-heptane, 2-methylhexane, 3-methylhexane, 2,2-dimethylpentane, 2,3-dimethylpentane, 2,4-dimethylpentane, 3,3-dimethylpentane, 3-ethylpentane, 2,2,3-trimethylbutane, n-octane, 2-methylheptane, 3-methylheptane, 4-methylheptane, 2,2-dimethylhexane, 2,3-dimethylhexane, 2,4-dimethylhexane, 2,5-dimethylhexane, 3,3 dimethylhexane, 3,4-dimethylhexane, 3-ethylhexane, 2,2,3-trimethylpentane, 2,2,4-trimethylpentane, 2,3,3-trimethylpentane, 2,3,4-trimethylpentane, 3-ethyl-2-methylpentane, 3-ethyl-3-methylpentane, 2,2,3,3-tetramethylbutane, n-nonane and isomers thereof, n-decane and isomers thereof, n-undecane and isomers thereof, n-dodecane and isomers thereof, n-tridecane and isomers thereof, n-tetradecane and isomers thereof, n-pentadecane and isomers thereof, and n-hexadecane and isomers thereof.

45. A method according to any of claims 34 to 44, wherein the monomer flow rate at standard temperature and pressure is from 0.2 to 50 sccm.

46. A method according to any of claims 34 to 45, wherein the power to monomer flow rate ratio is from 5 to 70 Watts/sccm.

47. A method according to any of claims 34 to 46, wherein the coating is built up in successive layers.

46. A method according to any of claims 34 to 47, wherein the plasma is formed by applying a radio frequency signal to the one or more monomer compounds, wherein the one or more monomer compounds are in the gaseous state.

47. A method according to any of claims 34 to 46, wherein the plasma is a pulsed wave plasma and/or a continuous wave plasma.
